(19) United States
(12) Patent Application Publication
(10) Pub. No.: US 2014/0118027 A1
(43) Pub. Date: May 1, 2014

(54) Mixed-Mode Circuits

(71) Applicant: Renesas Mobile Corporation, Tokyo (JP)

(72) Inventors: Ari Juhani VILANDER, Vantaa (FI); Jouni Kristian KAUKOVUORI, Vantaa (FI)

(73) Assignee: Renesas Mobile Corporation, Tokyo (JP)

(21) Appl. No.: 14/067,049

(22) Filed: Oct. 30, 2013

(30) Foreign Application Priority Data
Oct. 30, 2012 (GB) 1219522.8

(51) Int. Cl. H03K 5/153

(52) U.S. Cl. CPC H03K 5/153
USPC 327/1

(57) ABSTRACT

An apparatus for processing signals, arranged on an integrated circuit, comprises at least one analog input port that receives an input signal from outside of the integrated circuit, and a detector that detects an operation state of the apparatus based on the input signal. The detector provides at least one digital control/enable signal, which is dependent on the operation state of the apparatus, to another apparatus arranged on the integrated circuit.

### CROSS REFERENCE TO RELATED APPLICATION

This application claims the benefit under 35 U.S.C. §119(a) and 37 CFR §1.55 to UK patent application no. 1219522.8, filed on Oct. 30, 2012, the entire content of which is incorporated herein by reference.

### TECHNICAL FIELD

The present invention relates to integrated circuit (IC) development, and in particular to ICs which include RF/analog content.

### BACKGROUND

The following meanings for the abbreviations used in this specification apply:

AC alternating current

ADC analog-to-digital converter

DC direct current

IC integrated circuit

MCU micro controller unit

RF radio frequency

RFIC radio frequency integrated circuit

Currently, complex circuit designs—like RF transceivers—comprise various different mixed-mode circuits, for example: RF amplifiers, analog filters, blocks for digital computation, MCUs, power management, etc. Although the functionality is diverse and the variety of different blocks is large, the ICs should be as small as possible to keep the die size and component price small. In addition—or even as a consequence—ICs need to be placed into smaller and smaller packages to be desirable for the customers. When the package is small, however, the number of input/output pins can be rather limited.

However, the need for pins with RF transceivers is strong, for example: receivers and transmitters have several inputs and outputs, a digital interface towards baseband (DigRF) together with several reference clocks also require several pins, and there are test and monitoring pins, supply and ground pins, etc. Yet further, there has to be an adequate number of enable and control pins to support IC operation in different states and to support as many functions and modes as possible. Also, the IC should be able to be configured into several different modes to support as many products/platforms as possible with as few external components as possible.

Most conveniently, the IC can be configured into desired state(s) via (internal) digital control. However, that requires an MCU to be operational thus requiring active clocking, etc. In other words, the IC cannot be configured first since it requires the MCU and clock to activate controlling sequences. However, before the clock is available and the MCU is activated, the IC has to be activated first to generate the reference clock. Using additional enable or control pins to control the IC would solve the problem, but this is not desirable in view of the requirement to keep the die size small.

The number of pins could be increased with packages having less space between the pins. However, if the spacing is too small, the yield can be worsened. Also, more expensive packaging methods could be used but excessive testing time, high price, and poor yield must be avoided.

### SUMMARY

Exemplary embodiments of the present invention broadly aim at providing digital control to configure an IC into a desired state without adding digital control pins to the IC.

According to a first aspect, an exemplary embodiment provides an apparatus for processing signals, the apparatus being arranged on an IC, the apparatus comprising: at least one analog input port for receiving an input signal from outside of the IC; and a detector arranged to detect an operation state of the apparatus based on the input signal, wherein the detector is arranged to provide at least one digital control/enable signal, the at least one digital control/enable signal being dependent on the operation state of the apparatus, and wherein the detector is arranged to provide the at least one digital control/enable signal to another apparatus arranged on the IC.

According to a second aspect, an exemplary embodiment provides an IC comprising: a first apparatus; and a second apparatus, wherein the first apparatus comprises: at least one analog input port for receiving an input signal from outside of the IC; and a detector arranged to detect an operation state of the first apparatus based on the input signal, and provide at least one digital control/enable signal dependent on the operation state of the apparatus to the second apparatus.

According to a third aspect, an exemplary embodiment provides an IC comprising a foregoing apparatus.

According to a further aspect, an exemplary embodiment provides method of controlling an aforementioned apparatus, the method comprising: connecting the at least one analog input port to a signal source in case the apparatus is to be used, connecting the at least one analog input port to a first DC voltage in case the apparatus is not to be used and the other apparatus is to be used, and connecting the at least one analog input port to a second DC voltage in case the apparatus is not to be used and the other apparatus is to be enabled.

According to an exemplary embodiment, analog inputs of an IC are combined with digital control of the IC.

With such arrangement it is possible to spare pins. An RFIC may include blocks which are in use only in some cases. In other cases the blocks are unused and pins of it can be reused for controlling.

### BRIEF DESCRIPTION OF THE DRAWINGS

In the following the invention will be described by way of non-limiting exemplary embodiments thereof with reference to the accompanying drawings, of which:

FIGS. 1A and 1B are block diagrams illustrating different states of an IC;

FIG. 2 is a block diagram illustrating a combination of analog inputs of an IC with digital control of the IC according to an embodiment of the invention;

FIGS. 3A, 3B and 3C are block diagrams illustrating an implementation example of the invention; and

FIGS. 4A, 4B and 4C are block diagrams illustrating another implementation example of the invention.

### DETAILED DESCRIPTION

According to an exemplary embodiment of the invention, a non-active analog port of an IC is re-used as a controlling pin.

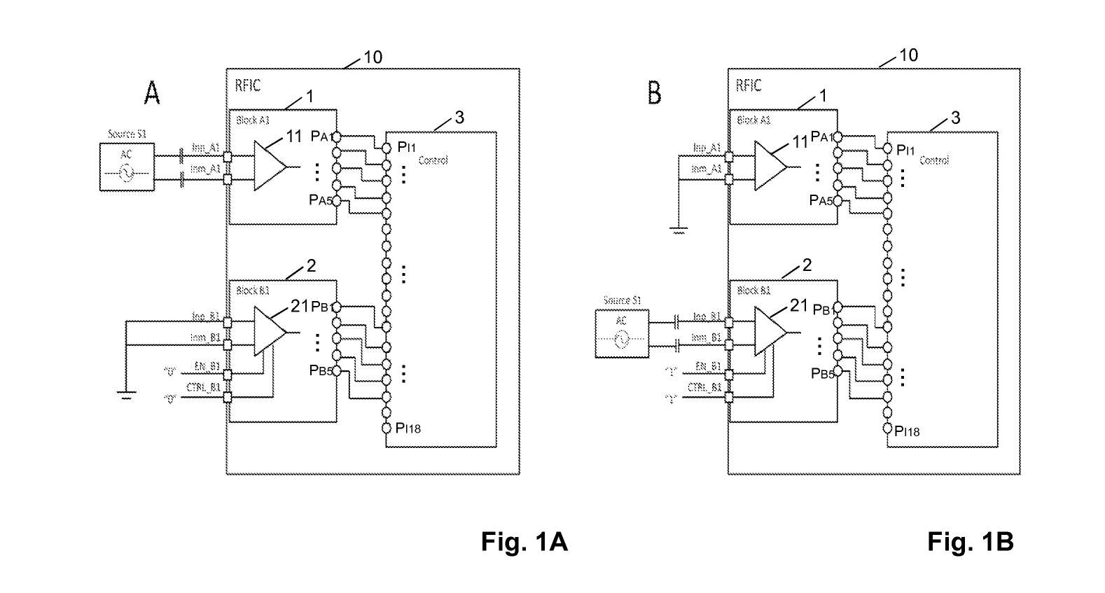

FIGS. 1A and 1B illustrate different states of an IC 10, e.g. an RFIC. The IC 10 comprises a block A1 1, a block Bl 2 and a control block 3.

The block A1 1 comprises analog input ports Inp_A1, Inm_A1 which may be connected to a signal source S1 or to ground, a driving circuit 11 for receiving signals from the analog input ports Inp_A1, Inm_A1 and processing the signals, and ports PA1-PA5 connected to ports PI1-PI5 of the control block 3.

The block B1 2 comprises analog input ports Inp_B1, Inm_B1 which may be connected to the signal source S1 or to ground, digital input ports EN_B1, CTRL_B1, a driving circuit 21 for receiving signals from the analog input ports Inp_B1, Inm_B1 and the digital input ports EN_B1, CTRL_B1 and processing the signals, and ports PB1-PB5 connected to ports PI12-P116 of the control block 3.

The control block 3 comprises ports PI1-PI18.

When the IC 10 is configured to state ‘A’ shown in FIG. 1A, block A1 1 is being activated, i.e. the analog input ports Inp_A1, Inm_A1 are connected to the signal source S1, and it can be internally controlled by the control block 3, while block B1 2 is redundant.

In state ‘B’ shown in FIG. 1B, block A1 1 is disabled, i.e. the analog input ports Inp_A1, Inm_A1 are connected to ground, and block B1 2 is activated, i.e. the analog input ports Inp_B1, Inm_B1 are connected to the signal source S1. However, block B1 2 requires an enable/control word to be set into a desired state, and an internal connection (digital control provided by control block 3) is not available yet.

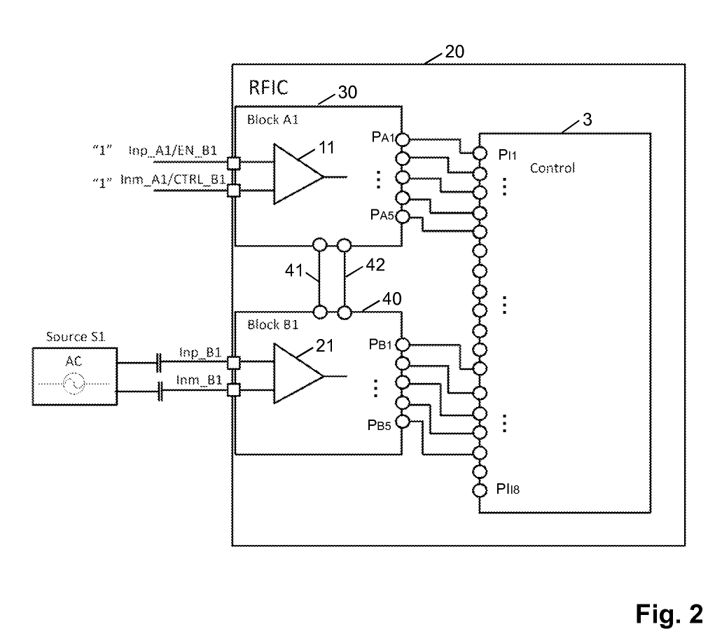

According to an exemplary embodiment illustrated in FIG. 2, non-used ports Inp_A1, Inm_A1 of block A1 30 of an IC 20, e.g. an RFIC, are used as digital input ports EN_B1, CTRL_B1 for providing an enable/control word to block B1 40 of the IC 20 via a control path 41, 42. Hence, the analog input ports of block A1 30 are reused to control/enable block B1 40. As a result, the number of external pins of the IC 20 is minimized and pins are efficiently used in both configurations, i.e. states ‘A’ and ‘B’. Redundant pins are avoided.

In particular, the digital input ports EN_B1, CTRL_B1 of block B1 2 in FIGS. 1A and 1B can be omitted in the configuration of FIG. 2, and the analog input ports Inp_A1, Inm_A1 of block A1 30 can be used for generating the enable/control word on the control path 41, 42 for block B2 40. The remaining components of the IC 20 are similar to those described with respect to FIGS. 1A and 1B and are not described again.

In other words, according to an exemplary embodiment, an apparatus (first apparatus) for processing signals, e.g. the block A1 30, arranged on an integrated circuit, e.g. the IC 20, comprises at least one analog input port, e.g. Inp_A1, Inm_A1, which receives an input signal from outside of the integrated circuit, and a detector (not shown in FIG. 2) which detects an operation state of the first apparatus based on the input signal, and outputs at least one digital control/enable signal, e.g. on the control path 41, 42, dependent on the operation state of the first apparatus, within the integrated circuit to another apparatus (second apparatus), e.g. the block B1 40, arranged on the integrated circuit, wherein the at least one digital control/enable signal contributes to setting an operation state of the second apparatus.

The at least one analog input port may be connectable to different sources, e.g. the source S1, ground, outside of the integrated circuit in accordance with the operation state of the first apparatus. The detector may detect a signal level from the input signal, and output the at least one digital control/enable signal dependent on the signal level, from at least one output path (e.g. connection of the detector with control path 41, 42) of the detector, within the integrated circuit, to the second apparatus. The detector may convert the input signal to a DC voltage signal, detect a level of the DC voltage signal, and output the at least one digital control/enable signal dependent on the level of the DC voltage signal.

The first apparatus may comprise a driving circuit, e.g. the driving circuit 11, for processing signals input from the signal source. The driving circuit has an input for receiving a voltage signal based on the input signal. The detector may detect a level of the voltage signal, and output the at least one digital control/enable signal dependent on the level of the voltage signal. The voltage signal may be a DC voltage signal and the detector may detect the level of the DC voltage signal. For example, the detector comprises a comparator.

The first apparatus may comprise a first operation state in which the first apparatus is in use and the at least one analog input port is connected to the signal source, which is an AC voltage, and the detector outputs the at least one digital control/enable signal with a value which sets the operation state of the second apparatus to disabled, and a second operation state in which the first apparatus is not in use and the at least one analog input port is connected to a first DC voltage, e.g. a supply voltage of the integrated circuit, and the detector outputs the at least one digital control/enable signal with a value which contributes to setting the operation state of the second apparatus to in use, e.g. to active.

The detector may have a first output path (e.g. connection with control path leg 41) for outputting a digital control signal within the integrated circuit to a digital control path of the second apparatus (e.g. connection of the second apparatus with control path leg 41) and a second output path (e.g. connection with control path leg 42) for outputting a digital enable signal within the integrated circuit to a digital enable path of the second apparatus (e.g. connection of the second apparatus with control path leg 42). The first apparatus may comprise a third operation state in which the at least one analog input port is connected to a second DC voltage, e.g. ground, and the first apparatus is not in use, and the detector outputs the digital control signal and the digital enable signal with values which contribute to setting the operation state of the second apparatus to enabled.

It is to be noted that a connection of the at least one analog input port to a DC voltage, which may be VDD or any voltage of possibly several available voltages, GND or something in between, or even outside these limits in some cases, leads to an operation state, where with different DC voltages different operation states can be set, and a connection of the at least one analog input port to an AC voltage leads to another state.

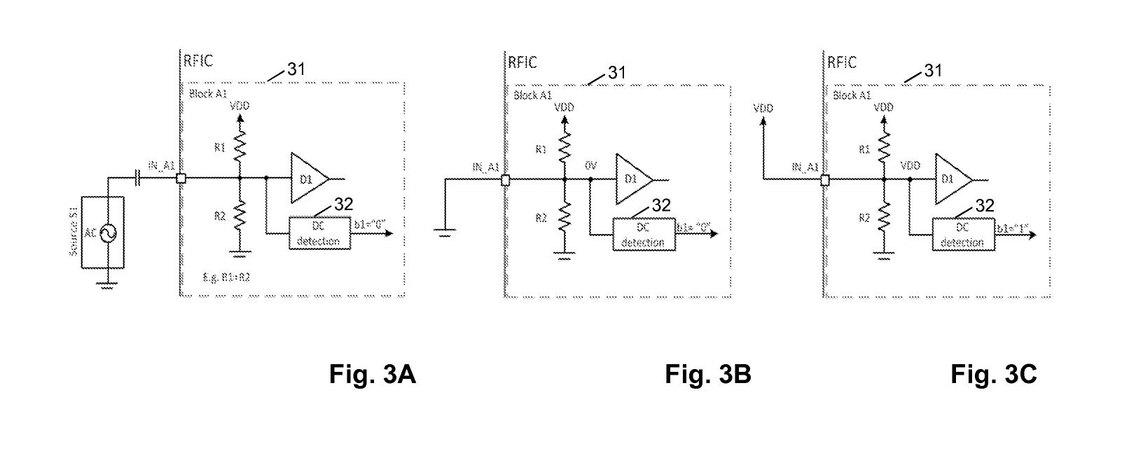

An implementation example of the invention is depicted in FIGS. 3A-3B. For clarity reasons, a single-ended view is shown.

In FIG. 3A, block A1 31 of an RFIC is in use and an AC signal source S1 is connected to input IN_A1 of block A1 31 through a capacitor. A voltage divider of block A1 31 with resistors R1, R2, which is connected to the input IN A1, receives an AC/DC converted input signal on the input IN_A1 and sets a DC voltage of a driving circuit D1 of block A1 31 on an input of the driving circuit D1 to a desired level between ground level and the level of a supply voltage VDD. For example, R1=R2. A DC detector 32 connected to the input of the driving circuit D1 senses the DC level on the input and, dependent on the sensed DC level, sets its output signal b1 to “0” in this example. The DC detector 32 can be implemented with a comparator or ADC, for example.

In FIG. 3B, block A1 31 is not in use, e.g. the driving circuit D1 is not in use, and IN_A1 is connected directly to GND. The DC detector 32 senses the DC level of the input of the driving circuit D1, i.e. 0V, and, based on the sensed DC level, sets its output b1 to “0” in this example.

In FIG. 3C, IN_A1 is connected to the supply voltage VDD of the integrated circuit. The DC detector 32 senses the DC level of the input of the driving circuit D1 and, based on the sensed DC level, sets its output b1 to “1” in this example. In alternative embodiments, the digital output of the DC detector 32 may be chosen in any suitable manner.

The output signal (control word) b1 can be connected to the control path 41, 42 shown in FIG. 2, which conveys the control word to block B1 40 as shown in FIG. 2. The driving circuit D1 may comprise the driving circuit 11 shown in FIG. 2. With the arrangements shown in FIGS. 3A, 3B, and 3C, unused inputs of A1 can be used to control block B1 to the desired state. For example, Inp_A1 can be used to enable block B1 (EN_B1) and Inm_A1 to control block B1 (CTRL_B1). EN_B1 and CTRL_B1 can be provided to block B1 via lines 41 and 42, respectively.

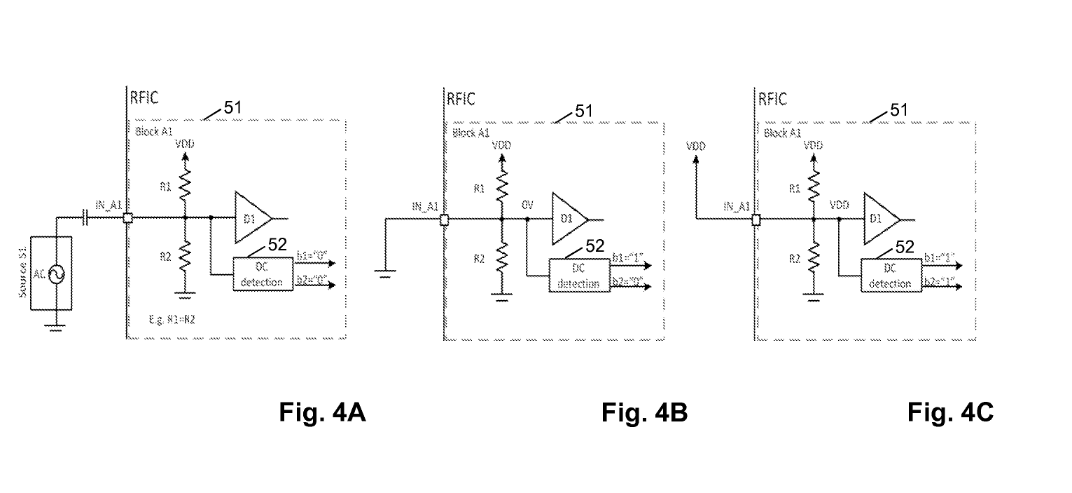

The arrangement shown in FIGS. 3A-3C can create three states of the input of the driving circuit: voltage divided, GND, and VDD. However, the output b1 only can provide two states, i.e. “0” and “1”, so one useful state remains unused. Therefore, a DC detector is proposed which generates two output signals. An exemplary arrangement is shown in FIGS. 4A-4C.

In FIG. 4A, block A1 51 of an RFIC is in use and an AC signal source S1 is connected to input IN_A1 of block A1 51 through a capacitor. A voltage divider of block A1 51 with resistors R1, R2, which is connected to the input IN_A1, receives an AC/DC converted input signal on the input IN_A1 and sets a DC voltage of a driving circuit D1 of block A1 51 on an input of the driving circuit D1 to a desired level between ground level and the level of a supply voltage VDD. For example, R1=R2. A DC detector 52 connected to the input of the driving circuit D1 senses the DC level on the input and, dependent on the sensed DC level, sets its output signals to b1=“0” and b2=“0” in this example. The DC detector 52 can be implemented with a comparator or ADC, for example. In alternative embodiments, the values of digital output signals of the DC detector 52 may be chosen in any suitable manner.

In FIG. 4B, block A1 51 is not in use, e.g. the driving circuit D1 is not in use, and IN_A1 is connected directly to GND. The DC detector 52 senses the DC level of the input of the driving circuit D1, i.e. 0V, and, based on the sensed DC level, sets its output b1 to “1” and its output b2 to “0” in this example.

In FIG. 4C, IN_A1 is connected to the supply voltage VDD of the integrated circuit. The DC detector 52 senses the DC level of the input of the driving circuit D1 and, based on the sensed DC level, sets its output b1 to “1” and its output b2 to “1” in this example.

Similar to the arrangement shown in FIGS. 3A-3C, the arrangement depicted in FIGS. 4A-4C can create three states of the input of the driving circuit: voltage divided, GND, and VDD. Then, referring back to FIG. 2, if block A1 30 comprises the three-state detector 52 as presented in FIGS. 4A-4C in both input ports of the driving circuit 11, if both input ports can be driven independently from each other, it can produce totally nine (3×3) different control states depending on voltage divided, GND, and VDD conditions at the inputs of the driving circuit 11. These nine control states can be used to control block B1, i.e. to generate EN_B1 and CTRL B1 signals. However, since EN_B1 and CTRL_B1 can only have four different states, there are five spare states, which can be used elsewhere within the RFIC or left unused. EN B1 and CTRL B1 may be provided to block B1 via lines 41 and 42, respectively. The amount of available input and control states can be changed depending on the system configuration, without departing from the invention.

According to an exemplary embodiment, a method of controlling block A1 30/block A1 31 is provided, in which the analog input ports Inp_A1, Inm_A1/IN_A1 are/is connected to a signal source in case block A1 30/block A1 31 is to be used, connected to a first DC voltage, e.g. a supply voltage of the block A1 30/block A1 31, in case block A1 30/block A1 31 is not to be used and block B1 40 is to be used, and connected to a second DC voltage, e.g. ground, in case block A1 30/block A1 31 is not to be used and block B1 40 is to be enabled. In an alternative embodiment, the logical output values given based on the supply voltage and the ground may be chosen differently.

It is to be understood that the above description is illustrative of the invention and is not to be construed as limiting the invention. Various modifications and applications may occur to those skilled in the art without departing from the true spirit and scope of the invention as defined by the appended claims.

What is claimed is:

1. An apparatus for processing signals, the apparatus being arranged on an integrated circuit, the apparatus comprising:
at least one analog input port for receiving an input signal from outside of the integrated circuit; and
a detector arranged to detect an operation state of the apparatus based on the input signal,
wherein the detector is arranged to provide at least one digital control/enable signal,
the at least one digital control/enable signal being dependent on the operation state of the apparatus, and
wherein the detector is arranged to provide the at least one digital control/enable signal to another apparatus arranged on the integrated circuit.

2. The apparatus of claim 1, wherein
the at least one analog input port is arranged to be connectable to different sources outside of the integrated circuit in accordance with the operation state of the apparatus, and/or
the detector is arranged to detect a signal level from the input signal, and provide the at least one digital control/enable signal dependent on the signal level, on at least one output path of the detector, within the integrated circuit, to the other apparatus.

3. The apparatus of claim 1, wherein the detector is arranged to convert the input signal to a DC voltage signal, detect a level of the DC voltage signal, and provide the at least one digital control/enable signal dependent on the level of the DC voltage signal.

4. The apparatus of claim 1, further comprising:
a driving circuit for processing signals input from a signal source, the driving circuit having an input for receiving a voltage signal based on the input signal,
wherein the detector is arranged to detect a level of the voltage signal, and provide the at least one digital control/enable signal dependent on the level of the voltage signal.

5. The apparatus of claim 4, wherein the voltage signal is a DC voltage signal and the detector is arranged to detect the level of the DC voltage signal.

6. The apparatus of claim 1, wherein the detector comprises a comparator.

7. The apparatus of claim 1, wherein the detector comprises an analog-to-digital converter.

8. The apparatus of claim 1, the apparatus comprising
a first operation state in which the apparatus is in use and the at least one analog input port is connected to a signal source, and the detector is arranged to provide the at least one digital control/enable signal with a value which sets the operation state of the other apparatus to disabled, and
a second operation state in which the apparatus is not in use and the at least one analog input port is connected to a first DC voltage, and the detector is arranged to provide the at least one digital control/enable signal with a value which contributes to setting the operation state of the other apparatus to in use.

9. The apparatus of claim 8, wherein the detector has a first output path for providing a digital control signal within the integrated circuit to a digital control path of the other apparatus and a second output path for providing a digital enable signal within the integrated circuit to a digital enable path of the other apparatus,
wherein the apparatus comprises a third operation state in which the at least one analog input port is connected to a second DC voltage and the apparatus is not in use, and the detector is arranged to output the digital control signal and the digital enable signal with values which contribute to setting the operation state of the other apparatus to enabled.

10. The apparatus of claim 1, wherein the at least one digital control/enable signal contributes to setting an operation state of the other apparatus.

11. An integrated circuit comprising:
a first apparatus; and
a second apparatus,
wherein the first apparatus comprises:
at least one analog input port for receiving an input signal from outside of the integrated circuit; and
a detector arranged to detect an operation state of the first apparatus based on the input signal, and provide at least one digital control/enable signal dependent on the operation state of the apparatus to the second apparatus.

12. The integrated circuit of claim 11, comprising:
a first mode in which the at least one analog input port of the first apparatus is connected to a signal source and the operation state of the first apparatus is set to in use, and
a second mode in which the at least one analog input port of the first apparatus is connected to a DC voltage and the operation state of the first apparatus is set to unused, and the analog input port of the second apparatus is connected to the signal source and the operation state of the second apparatus is set to in use.

13. The integrated circuit of claim 11, wherein the detector is arranged to provide the at least one digital control/enable signal to the second apparatus within the integrated circuit.

14. The integrated circuit of claim 11, wherein the at least one digital control/enable signal contributes to setting an operation state of the second apparatus.

15. An integrated circuit comprising an apparatus for processing signals, the apparatus being arranged on an integrated circuit, the apparatus comprising:
at least one analog input port for receiving an input signal from outside of the integrated circuit; and
a detector arranged to detect an operation state of the apparatus based on the input signal,
wherein the detector is arranged to provide at least one digital control/enable signal,
the at least one digital control/enable signal being dependent on the operation state of the apparatus, and
wherein the detector is arranged to provide the at least one digital control/enable signal to another apparatus arranged on the integrated circuit.

16. A method of controlling an apparatus for processing signals, the apparatus being arranged on an integrated circuit, the apparatus comprising at least one analog input port for receiving an input signal from outside of the integrated circuit and a detector arranged to detect an operation state of the apparatus based on the input signal, the detector being arranged to provide at least one digital control/enable signal, the at least one digital control/enable signal being dependent on the operation state of the apparatus, wherein the detector is arranged to provide the at least one digital control/enable signal to another apparatus arranged on the integrated circuit, the method comprising:
connecting the at least one analog input port to a signal source in case the apparatus is to be used, connecting the at least one analog input port to a first DC voltage in case the apparatus is not to be used and the other apparatus is to be used, and connecting the at least one analog input port to a second DC voltage in case the apparatus is not to be used and the other apparatus is to be enabled.
